(19) United States
(12) Patent Application Publication
(10) Pub. No.: US 2020/0194501 A1
(43) Pub. Date: Jun. 18, 2020

(54) IMPLEMENTING PHASE CHANGE MATERIAL-BASED SELECTORS IN A CROSSBAR ARRAY

(71) Applicant: TETRAMEM INC., Newark, CA (US)

(72) Inventor: Ning Ge, Newark, CA (US)

(73) Assignee: TETRAMEM INC., Newark, CA (US)

(21) Appl. No.: 16/218,786

(22) Filed: Dec. 13, 2018

(51) Int. Cl. H01L 27/24; H01L 45/00; G11C 13/00

(52) U.S. Cl. CPC H01L 27/2481; H01L 45/06; H01L 45/144; G11C 13/0069; H01L 45/122; G11C 13/0004; G11C 13/004; H01L 45/1253

(57) ABSTRACT

Implementing phase change material-based selectors in a crossbar array are disclosed. In some implementations, an apparatus comprises: a plurality of row wires; a plurality of column wires; and a plurality of cross-point devices connecting the plurality of row wires and the plurality of column wires. Each cross-point devices comprises: a memristor device and a selector device formed on the memristor device. The selector device is configured to when in an OFF state, selectively transmit a programming signal to the memristor device; and switch the memristor device to a predefined resistance state when the programming signal includes a voltage pulse higher than a predefined threshold voltage of the selector device and shorter than a crystallization time of the selector device. The selector device is further configured to, when selectively transmitting the programming signal to the memristor device, temporarily switch itself from the OFF state into an ON state.

### TECHNICAL FIELD

The present disclosure generally to crossbar arrays and more specifically relates to implementing phase change material-based selectors in a crossbar array.

### BACKGROUND

A high performance neural network usually requires easily implementation of its training and inferencing sessions. These training and inferencing sessions may be accomplished by large-scale crossbar arrays. A crossbar array may include horizontal metal wire rows and vertical metal wire columns (or other electrodes) intersecting with each other, with cross-point devices formed at the intersecting points.

When a neural network involves a large number of devices in a crossbar array, a large sneak current may be present and device appropriate operations may be difficult to archive. These technical challenges remain to be addressed.

### SUMMARY

An example apparatus comprises: a plurality of row wires; a plurality of column wires; and a plurality of cross-point devices connecting the plurality of row wires and the plurality of column wires. Each cross-point devices comprises: a memristor device and a selector device formed on the memristor device. The selector device is configured to when in an OFF state, selectively transmit a programming signal to the memristor device; and switch the memristor device to a predefined resistance state when the programming signal includes a voltage pulse higher than a predefined threshold voltage of the selector device and shorter than a crystallization time of the selector device.

The selector device is, in some implementations, further configured to, when selectively transmitting the programming signal to the memristor device, temporarily switch itself from the OFF state into an ON state.

The selector device is, in some implementations, further configured to, when in the OFF state, block a voltage pulse that is lower than the predefined threshold voltage of the selector device.

The selector device is, in some implementations, further configured to switch from the OFF state to the ON state permanently when a high temperature treatment followed by a slow cooling down process is applied to the selector device.

The selector device is, in some implementations, further configured to switch from the ON state to the OFF state when the high temperature treatment followed by a fast cooling down process is applied to the selector device.

In some implementations, a temperature of the high temperature treatment is higher than 150 degree Fahrenheit.

In some implementations, the predefined resistance state is an ON state of the memristor device and the crystallization time is within 100 nanoseconds.

The memristor device, in some implementations, comprises one of: a memristor, a Ferroelectric Resistance Switching Memory, Phase Change Memory, a Resistive Random-Access Memory (RRAM or ReRAM), a Magnetoresistive Random-Access Memory (MRAM), a Dynamic random-access memory (DRAM), or other devices with tunable resistance.

In some implementations, a material from which the selector device is made may be chalcogenide materials or other phase change materials.

In some implementations, the memristor device comprises an outer bottom electrode and a first functional layer formed on the outer bottom electrode, and the selector device comprises a second functional layer and an outer top electrode formed on the second functional layer.

The memristor device, in some implementations, further comprises an inner bottom electrode formed between the first functional layer and the second functional layer.

The selector device, in some implementations, further comprises an inner top electrode formed between the second functional layer and the inner bottom electrode.

The cross-point device, in some implementations, further comprises an intermediate layer formed between the memristor device and the selector device.

An example method of operating a crossbar array comprising: programming a plurality of memristor devices with a programming signal via a plurality of selector devices that are in an OFF state. Each of the selector devices is switched to an ON state temporarily when the programming signal includes a voltage that is higher than a predefined threshold voltage of each of the selector devices. The method further comprises: switching the plurality of selector devices from the OFF state to an ON state by applying a high temperature treatment followed by a slow cooling process; and accessing the plurality of memristors during one or more inferencing operations.

The method further comprises: switching the plurality of selector devices from the ON state to the OFF state by applying a high temperature treatment followed by a fast cooling process, after accessing the plurality of memristors and before programing the plurality of memristor devices with a next programming signal.

Accessing the plurality of memristors, in some implementations, includes reading from or writing to the plurality of memristors.

### BRIEF DESCRIPTION OF THE DRAWINGS

FIG. 1 is a block diagram illustrating an example crossbar array in accordance with some implementations.

FIG. 2 is a block diagram illustrating an example structure of a cross-point device in accordance with some implementations.

FIG. 3 is a block diagram illustrating example characteristic of a selector in accordance with some implementations.

FIG. 4 is a block diagram illustrating example characteristic of a cross-point device having a selector and a memristor in accordance with some implementations.

FIG. 5 is a block diagram illustrating a first example structure of a cross-point device in accordance with some implementations.

FIG. 6 is a block diagram illustrating a second example structure of a cross-point device in accordance with some implementations.

FIG. 7 is a block diagram illustrating a third example structure of a cross-point device in accordance with some implementations.

FIG. 8 is a block diagram illustrating a fourth example structure of a cross-point device in accordance with some implementations.

FIG. 9 is a flowchart illustrating an example method for implementing a neural network using one or more crossbar arrays in accordance with some implementations.

FIG. 10 is a block diagram illustrating an example computing system for implementing a neural network using one or more crossbar arrays in accordance with some implementations.

The implementations disclosed herein are illustrated by way of example, and not by way of limitation, in the figures of the accompanying drawings. Like reference numerals refer to corresponding parts throughout the drawings.

### DETAILED DESCRIPTION

Phase change cells have been implemented in fabrication technologies. Phase change cells may suffer from limited endurance and large resistance drift, which may prevent phase change cells from being used as memory or implemented in a neural network.

The present disclosure, however, provide technologies relating to implementing phase change cells as the scalable and stackable selector. For example, when a high-speed pulse is used to switch a target cell within 1-PCM 1-memristor cell, the PCM cell may be temporarily switched ON and the memristor may be programmed to present either a higher or a lower resistance level depending on the voltage polarity. If the voltage pulse is short enough, the PCM may not have time to crystallize and thus may automatically return to its amorphous state, e.g., the OFF state. This way, memristors present in a crossbar array may be programmed individually. When such a neural network is used for inferencing after training, computing chips may be heated up to above the crystallization temperature of PCM, which is usually a low enough temperature and does not affect the resistance of memristors; the chips may then be cooled down slowly to let PCM cells crystallize and stay in their ON state. The chips then become ready for inferencing application. When the chips are heated up and then cooled down quickly, the PCM cells are placed in their amorphous phase, corresponding to the OFF state; as a result, the chips become ready for learning.

The technologies described in the present disclosure may provide the following technical advantages. First, in a large-scale crossbar array, sneak current paths and half-select devices thus formed may cause the unwanted cross-point devices to be read and written, increasing the likelihood of read and write error. A phase change material-based selector may reduce sneak currents. Second, a phase change material-based selector may be turned ON and OFF permanently or temporarily, providing more flexible and easier applications (e.g., training and inferencing) in a neural network, as well as simpler circuit design of cross-point devices. Third, the combination of a phase change material-based selector and a memristor in a cross-point device may be implemented in different example stack of layers. These different combinations may simplify the fabrication process and reduce surface issues among layers.

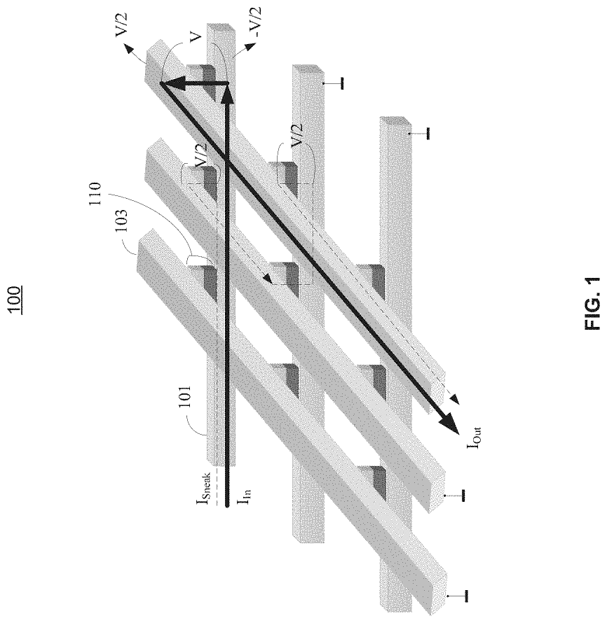

FIG. 1 is a block diagram illustrating an example crossbar array 100 in accordance with some implementations.

The crossbar array 100 may include a plurality of row wires such as a first row wire 101, a plurality of column wires such as a first column wire 103, and a plurality of cross-point devices such as a cross-point device 110 connecting the first row wire 101 and the first column wire 103. Conventionally, the cross-point device includes only one memristor without a selector. An example electrical addressing scheme for either a reading or writing operation involves applying V/2 to a row wire, and −V/2 to a column wire, resulting in a total voltage drop of V across the selected cross-point device. This operation, however, may also result in an incidental voltage drop of V/2 on all other cross-point devices located in the selected row wire and the selected column wire. These incidentally selected cross-point devices may be referred to as half-selected devices and suffer unwanted resistance change due to the unwanted voltage (V/2) being applied on them. This phenomenon is also referred to as the half-select phenomenon.

Sneak current may also exist. For example, in addition to the currents flowing through the selected cross-point device, sneak path currents, such as the current I_{Sneak}, may also flow through the half-selected cross-point devices and some unselected cross-point devices located within the crossbar array.

These sneak currents may cause calculations or operations errors when the crossbar array 100 is implemented to provide neural network applications. Furthermore, as the size of the crossbar array increase, the accumulation of all sneak currents may be significant. The size of the crossbar array may thus be limited by the sneak currents, which can saturate the driving circuitry and generate unwanted Joule heating during writing/erasing operations. In addition, sneak paths limit the reading operation because of the large signal to background current level. The ON state of the memristor is especially relevant because large sneak currents run through those ON state devices because of their relatively low resistance.

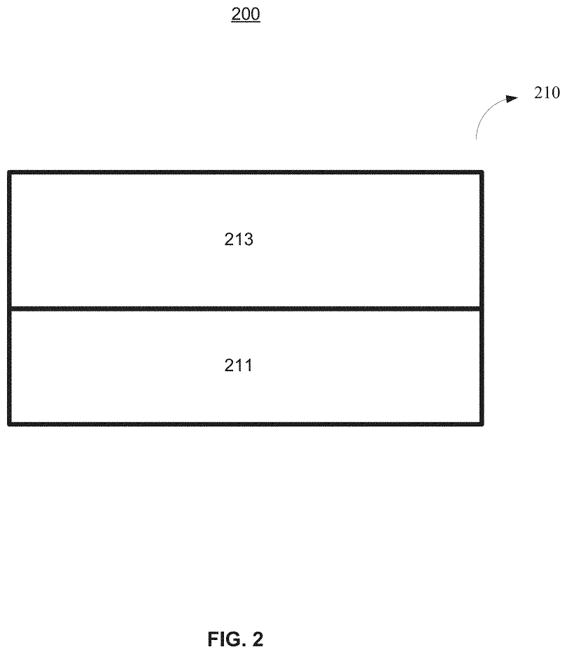

FIG. 2 is a block diagram illustrating an example structure 200 of a cross-point device 210 in accordance with some implementations.

As shown in FIG.2, the example cross-point device 210 includes a memristor device 211 and a selector device (or a selector, for short) 213 formed on the memristor device 211. In some implementations, the selector device 213 may be serially connected to the memristor device 211. The selector device 213 may be of the following characteristics.

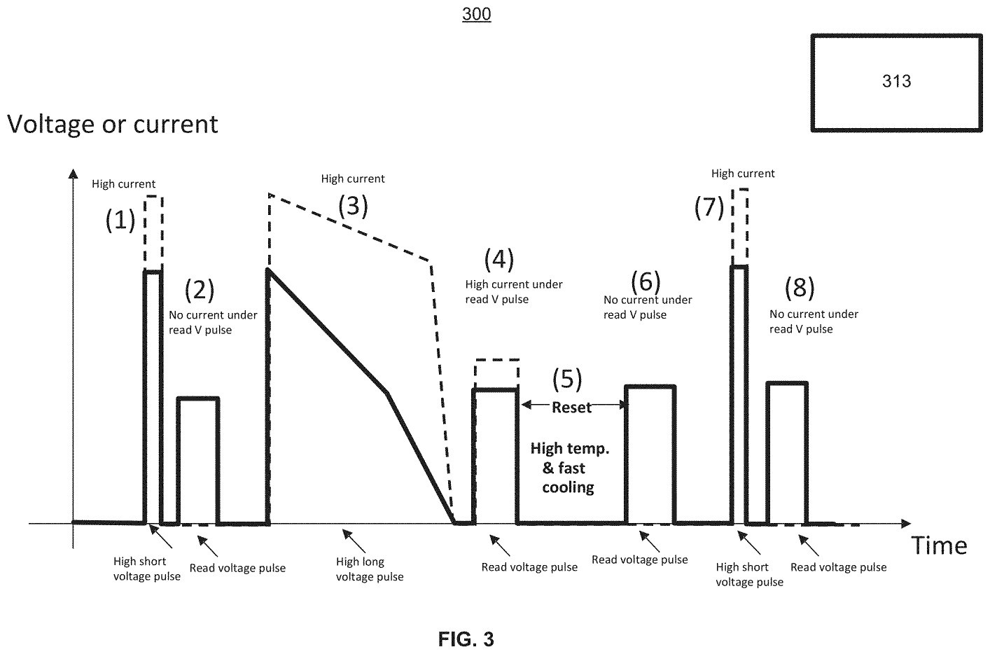

FIG. 3 is a block diagram illustrating example characteristics 300 of a selector 310 in accordance with some implementations. The solid line represents the voltage applied on the selector device 310; the dashed line represents the current generated and passed through the selector device 310.

In some implementations, the selector device 310 is made of a Phase Change Material (PCM), which is capable of staying in an insulating state (or high resistance state, e.g. higher than 100K Ω) during its amorphous phase, switching temporarily to a conductive state (or low resistance state, e.g. lowing than 100Ω) during its metallic phase or crystalline phase, and switched back to the insulating state during its amorphous phase. In some implementations, the Phase Change Material of which the selector device 310 is made includes Ge2SbTe5, chalcogenide materials, or other phase change materials.

Example electrical behaviors of the selector device 310 over different time points include the following:

(1) Initially, when in the amorphous phase, the selector device 310 is in a high resistance state (e.g. having a resistance that is higher than 100k Ω). The high resistance state is also referred to as the “OFF” state. Under a high, but short, voltage pulse, which is a voltage pulse higher than a threshold voltage of the selector device 310 and shorter than a crystalline time of the selector device 310 (e.g. 10 V for less than 100 nanoseconds), the selector device 310 is switched to a low resistance state (e.g. having a resistance that is lower than 100Ω). The low resistance state is also referred to as the “ON” state.

The ON state can be indicated by the high current observed temporarily, corresponding to a phase change to metallic phase under the high electrical pulse. Because the voltage pulse is short and the cooling process is fast (e.g. under 100 nanoseconds), the phase change material does not have sufficient time to crystallized and its amorphous phase is maintained due to the low temperature. The selector device 310 is switched back to the OFF state and remains in the OFF state following the high and short voltage pulse.

It should be noted that the amorphous phase here refers to that a current path in the selector device is blocked due to a portion of the selector device being in the amorphous state, it does not mean that the entire selector needs to be in the amorphous state. Other part of the selector device may be in a polycrystalline, monocrystalline, or metallic state as long as the selector device remains in the high resistance state. Also, in some implementations, the crystalline time of the selector 310 is less than 100 nanoseconds.

(2) Due to the selector device 310 being in the OFF state, no current under a read voltage pulse applied on the selector device 310 is detected.

(3) However, if a high and long voltage pulse (e.g. 10 V for more than 1 millisecond) is applied on the selector device 310, the phase change material of which the selector device 310 is made would have sufficient time to crystalize during the long cooling process. In some implementation, a long pulse with decreasing voltage is equivalent to a slow cooling process. Therefore, the phase change material may turn into a crystalline phase at neural network operation temperature. The selector device 310 is then switched to the ON state and remains in the ON state following the high and long voltage pulse and a slow cooling process.

(4) Since the selector device 310 is turned to the ON state and thus has a low resistance, a high current is observed under a read voltage pulse.

(5) The crystalline low resistance state can be RESET to the amorphous high resistance state by a high temperature treatment (e.g. higher than 150 degree Fahrenheit for some materials) followed by a fast cooling process (e.g. less than 100 nanoseconds).

(6) After such a RESET, the material turns into a high resistance state again, as indicated by the nearly zero current level under read voltage after the RESET treatment.

(7) The material is thus reset to its initial amorphous high resistance state, which can be temporarily switched to its ON state as the characteristic and the result in stage (1).

(8) After the short and high voltage pulse, the material returns to its high resistance state automatically, as indicated by the lack of detectable current under a read voltage as the characteristic and the result in stage (2).

The electrical behaviors illustrated in FIG. 3 may improve crossbar array performance and accuracy by mitigating the half-select and sneak path current issues. Some example properties provided by such phase change materials are that it provides a high resistance state, when a low voltage is applied and a temporarily low resistance state when a high voltage is applied.

These properties can ensure that the unselected cross-point devices or half-selected cross-point devices remain in high resistance states and that only the selector device in the selected cross-point device is in a low resistance state during the short, high voltage pulse, which enables sufficient voltage and current to drop on the selected memristor (which may be serially connected with the selector) and switch the selected memristor. Voltages dropped on unwanted cross-point devices are blocked by the selector device: because the voltage is lower than the threshold voltage of the selector device.

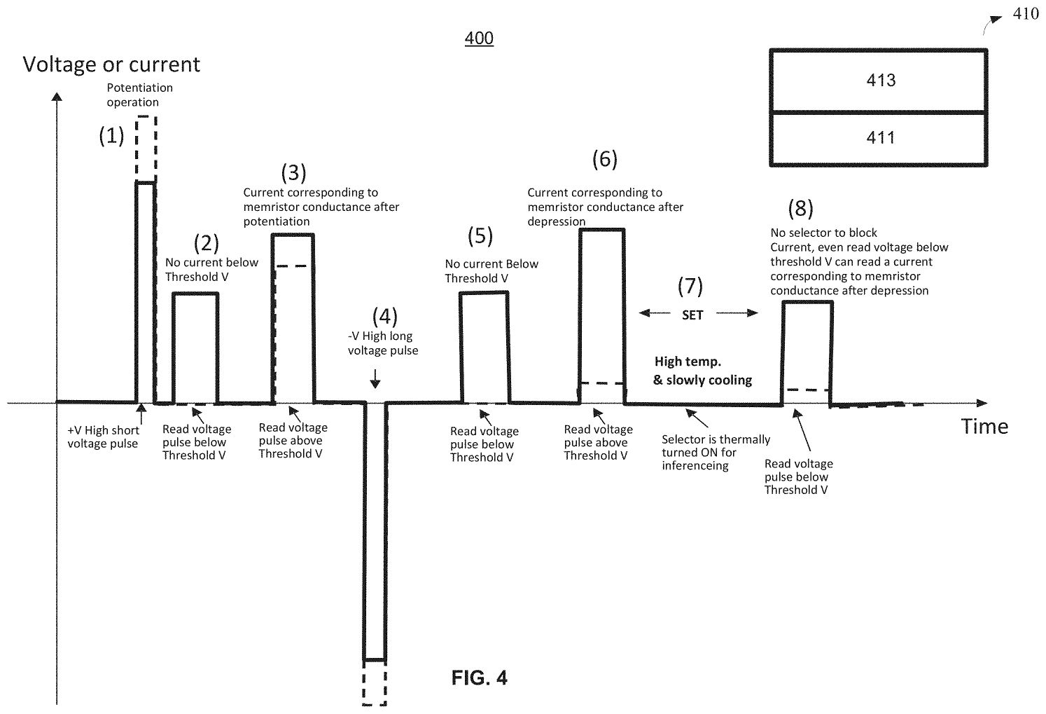

FIG. 4 is a block diagram illustrating example characteristic 400 of a cross-point device 410 having a selector and a memristor in accordance with some implementations.

As shown in FIG. 4, the cross-point device 410 includes a selector device 413 formed on the memristor device 411. In some implementations, the selector device 413 may be serially connected to the memristor device 411. The solid line represents the voltage applied on the cross-point device 410; the dashed line represents the current generated and passed through the cross-point device 410.

In some implementations, the selector device 413 is a phase change material which is capable of staying in an insulating or high resistance state (e.g. having a resistance that is higher than 100K Ω) during its amorphous phase, switching temporarily to a conductive or low resistance state (e.g. having a resistance that is lower than 100Ω) during its metallic phase or crystalline phase, and switched back to the insulating status during its amorphous phase. In some implementations, the phase change material of which the selector device 413 is made includes Ge2SbTe5, chalcogenide materials, or other phase change materials.

In some implementations, the memristor device 411 includes a memristor, a Phase Change Memory, a Resistive Random-Access Memory (RRAM or ReRAM), a Magnetoresistive Random-Access Memory (MRAM), or other devices with tunable resistance.

Electrical behaviors of the cross-point device 410 can be explained along the time axis of FIG. 4 as follows:

(1) Initially the selector device 413, in amorphous phase, is in high resistance state (e.g. higher than 100K Ω) or so called “OFF” state. Under a high but short voltage pulse, which is a voltage pulse higher than a threshold voltage of the selector device 413 and shorter than a crystalline time of the selector device 413 (e.g. 10 V for less than 100 nanoseconds), the selector device 413 is switched to low resistance state (e.g. lower than 100Ω) or so called “ON” state temporarily. The ON state can be indicated by the high current observed temporarily, corresponding to a phase change to metallic phase under the high electrical pulse. Because the voltage pulse is short and the cooling process is fast (e.g. within 100 nanoseconds), the material does not have sufficient time to crystallized, its amorphous phase is maintained at low temperature. The selector device 413 is switched back to OFF state and remains OFF state after the high and short voltage pulse. Once the selector device 413 changes to its low resistance state, the applied short but high voltage pulse drops on the memristor 411 (called a synapse in neural network term) in series with the selector device 413 and switches the memristor 411 into its low resistance state (called potentiation in neural network term). This potentiate is a non-volatile change of memristor resistance, which remains until the memristor is switched again.

Therefore, the selector device 413 in OFF state is configured to selectively transmit a programming signal such as a programming voltage to the memristor device 411 and switch the memristor device 411 to ON state when the programming signal is a voltage pulse higher than a threshold voltage of the selector device 413 and shorter than a crystallization time of the selector device 413.

In some implementations, when the selector device 413 selectively transmits the programming signal to the memristor device 411, the selector device 413 is switched to ON state temporarily and switch to OFF state after the transmission.

In some implementations, the crystalline time of the selector device 413 is less than 100 nanoseconds.

(2) After the short but high pulse, the selector device 413 quickly returns back to its high resistance state. Due to the OFF state of the selector device 413, no current under a read voltage pulse below the threshold voltage of the selector device 413 applied on the selector device 413 is detected.

(3) However, when a read voltage above the threshold voltage of the selector device 413 is applied, this read voltage can turn on the selector device 413 temporarily and thus is able to measure the resistance of the memristor device 411 synapse by obtaining a high reading current.

(4) The memristor device 411 (synapse) can be switched back to its high resistance state (called depression in neural network terms) by using a high but short voltage pulse with opposite voltage polarity, which first turns ON the selector device 413 temporarily and then switches the memristor 411 (synapse) to its high resistance state (i.e. depression).

(5) If a voltage below the ON-switching threshold voltage of the selector device 413 is used to read the cross-point device 410, almost no current can be detected because the selector device 413 is in its high resistance state after the depression operation with short and high opposite voltage pulse.

(6) However, if a voltage above the ON-switching threshold voltage of the selector device 413 is used to read the cross-point device 410, a current can be detected because the selector device 413 is turned ON temporarily by this high read voltage. Since the memristor device 411 (synapse) has been switched to its relatively high resistance state by the depression operation in (4), only a small current can be detected, suggesting the memristor device 411 (synapse) is its high resistance state.

(7) After the memristor device 411 (synapse) is switched to the target value by the potentiation and depression operations, the selector can now be SET to its low resistance state by a high temperature treatment (e.g. higher than 150 degree Fahrenheit for certain phase change materials) followed by a slow cooling down process (e.g. more than 10 seconds) to crystallize the phase change materials in the selector device 413.

(8) After the selector device 413 is SET to its low resistance state or ON state, even a read voltage below the ON-switching threshold voltage of the selector device 413 can now be used to measure the conductance of the memristor device 411 (synapse) directly. This may be used for inferencing operations.

After the reading process is completed, the crystalline low resistance state can be RESET to the amorphous high resistance state by a high temperature treatment (e.g. higher than 150 degree Fahrenheit for some phase change materials) followed by a fast cooling process (e.g. less than 100 nanoseconds for some phase change materials). Another programming signal can be introduced to program the memristor device 411 again and repeat the operation in (1).

Example Structures of a Cross-point Device

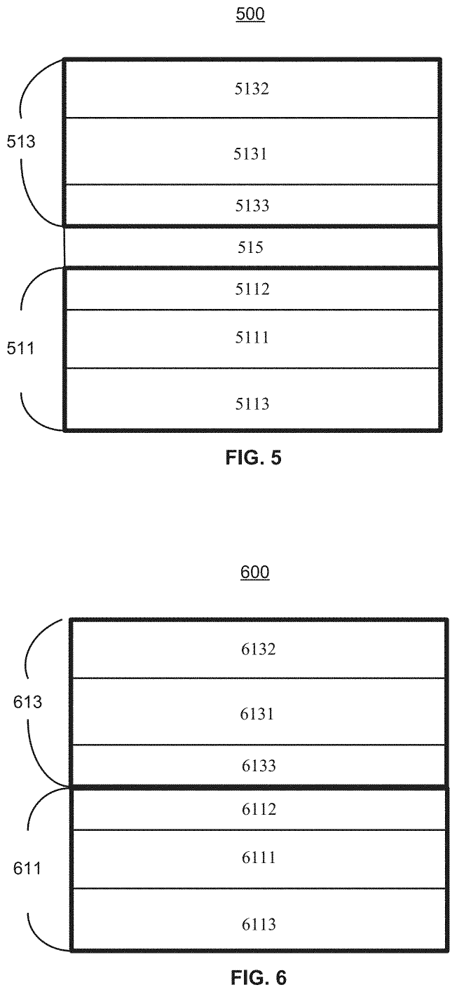

FIG. 5 is a block diagram illustrating a first example structure 500 of a cross-point device in accordance with some implementations.

As shown in FIG. 5A, the cross-point device 500 includes a memristor device 511, an intermediate layer 515 formed on the memristor device 511, and a selector device 513 formed on the intermediate layer 515. The memristor device 511 includes an outer bottom electrode 5113, a first functional layer 5111 formed on the outer bottom electrode 5113, and an inner bottom electrode 5112 formed on the first functional layer 5111. And the selector device 513 includes an inner top electrode 5133, a second functional layer 5131 formed on the inner top electrode 5133, and an outer top electrode 5132 formed on the second functional layer 5131.

FIG. 6 is a block diagram illustrating a second example structure 600 of a cross-point device in accordance with some implementations.

As shown in FIG. 6, the cross-point device 600 includes a memristor device 611, and a selector device 613 formed on the memristor device 611. The memristor device 611 includes an outer bottom electrode 6113, a first functional layer 6111 formed on the outer bottom electrode 6113, and an inner bottom electrode 6112 formed on the first functional layer 6111. And the selector device 613 includes an inner top electrode 6133, a second functional layer 6131 formed on the inner top electrode 6133, and an outer top electrode 6132 formed on the second functional layer 6131.

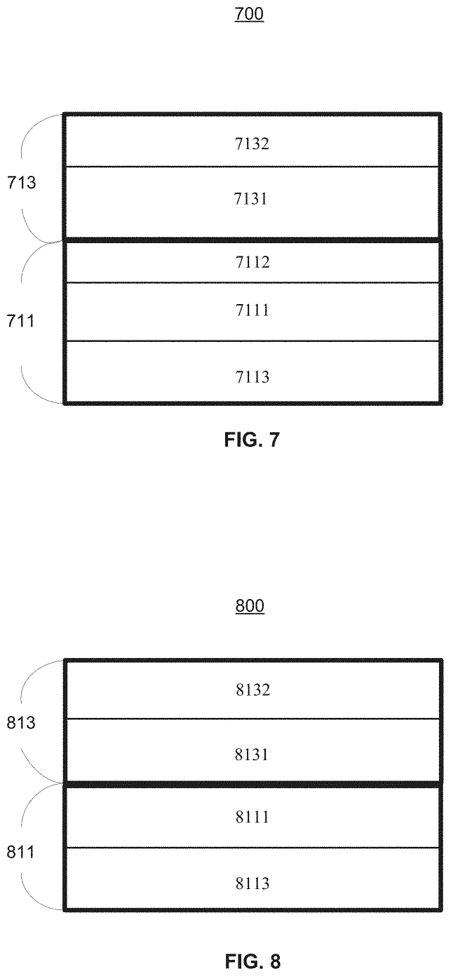

FIG. 7 is a block diagram illustrating a third example structure 700 of a cross-point device in accordance with some implementations.

As shown in FIG. 7, the cross-point device 700 includes a memristor device 711, and a selector device 713 formed on the memristor device 711. The memristor device 711 includes an outer bottom electrode 7113, a first functional layer 7111 formed on the outer bottom electrode 7113, and an inner bottom electrode 7112 formed on the first functional layer 7111. And the selector device 713 includes a second functional layer 7131, and an outer top electrode 7132 formed on the second functional layer 7131. The inner bottom electrode 7112 is formed as a common electrode of the memristor device 711 and the selector device 713.

FIG. 8 is a block diagram illustrating a fourth example structure 800 of a cross-point device in accordance with some implementations.

As shown in FIG. 8, the cross-point device 800 includes a memristor device 811, and a selector device 813 formed on the memristor device 811. The memristor device 811 includes an outer bottom electrode 8113, and a first functional layer 8111 formed on the outer bottom electrode 8113. And the selector device 813 includes a second functional layer 8131, and an outer top electrode 8132 formed on the second functional layer 8131. The first functional layer 8111 and the second functional layer 8131 may be in contact with each other.

In some implementations, a material of the electrodes (including electrodes 5113, 5112, 5133, 5132, 6113, 6112, 6133, 6132, 7113, 7112, 7132, 8113, and 8132) may include metals such as W, Al, Cu, Pt, Ir, Ru, Pd, Au, or metal compounds such as TiN, TaN, WN, RuO₂, IrO₂.

In some implementations, a material of the first functional layer (e.g., the first functional layer 5111, 6111, 7111, and 8111) of the memristor device (e.g., the memristor device 511, 611, 711, and 811) may include transition metal oxides such as TaOₓ, HfOₓ, ZrOₓ, TiOₓ, AlOₓ, WOₓ, and NiOₓ or nitrides, such as AlN, GaN, and AlGaN.

In some implementations, a material of the second functional layer (e.g., the second functional layer 5131, 6131, 7131, and 8131) of the selector device (e.g., the selector device 513, 613, 713, and 813) may include Ge2SbTe5, chalcogenide materials, or other phase change materials.

In some implementations, a material of the intermediate layer 515 include metals such as W, Al, Cu, Pt, Ir, Ru, Pd, Au, or metal compounds such as TiN, TaN, WN, RuO₂, IrO₂. The intermediate layer 515 is used to bond or connect the memristor device 511 with the selector device 513.

Applications in Neural Network

The 1PCM-1Memristor will form 2D arrays for multiple applications. In the application of neural network, there will be training and inferencing operations. In some implementations, the inferencing operation includes image recognition, image classification, data interpretation, or data analysis.

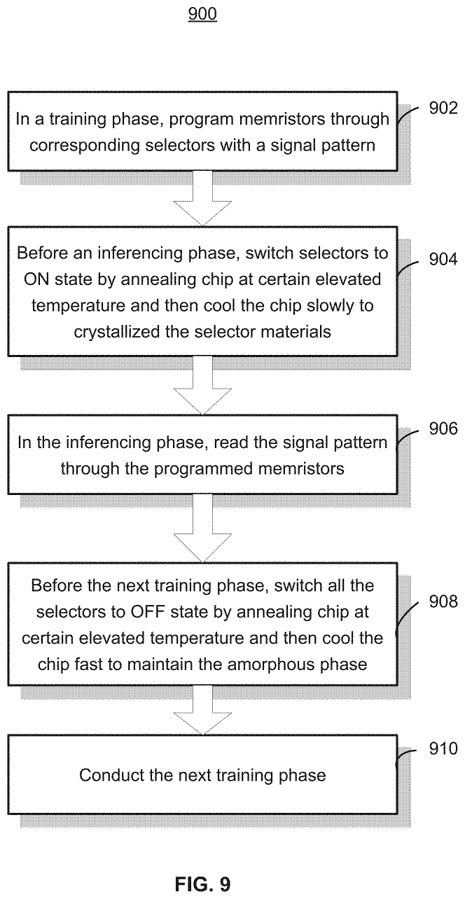

FIG. 9 is a flowchart illustrating an example method 900 for implementing a neural network using one or more crossbar arrays in accordance with some implementations.

During the training phase, the memristor devices such as a memristor device 411 in the crossbar array will be selected to program to certain resistances by applying a programming signal such as a signal pattern with corresponding voltage upon the memristor devices one by one (step 902). In some implementations, the signal pattern may be a data array, such as image data input parameters including number of images, image height, image width, number of channels, and number of levels per pixel.

It should be noted that in the beginning of the training phase, all the selector devices remain in their high resistance states or so called OFF state. When programming a target memristor device, the selector device will be turned ON temporarily, switch the target memristor device to target resistance, and be turned OFF after the programming.

After the training phase of the neural network, it turns to the inferencing phase (the application of a trained network to new data).

Before the inferencing phase, all the selector devices are SET or switched to their low resistance state or ON state permanently by a high temperature treatment (e.g. higher than 150 degree Fahrenheit) or a SET voltage (e.g. a voltage higher than a threshold voltage of the selector devices 413) to the entire crossbar array followed by a slow cooling process (e.g. more than 10 seconds) (step 904).

In the inferencing phase, read the signal pattern through the programmed memristor devices such as the memristor device 411 and send the output data to a storage (step 906).

Whenever the neural network needs to be reprogrammed again, all the selector devices are RESET to their high resistance states or OFF states by a high temperature treatment (e.g. higher than 150 degree Fahrenheit) followed by a fast cooling process (e.g. less than 100 nanoseconds) (step 908).

The next training phases are triggered with a new programming signal. (step 910)

In some implementations, the neural networks can be stacked upon each other to form 3D neural networks using a variety of 3D architectures, such as, by normal horizontal stacking, vertical stacking by forming devices at the edge of the electrode layers.

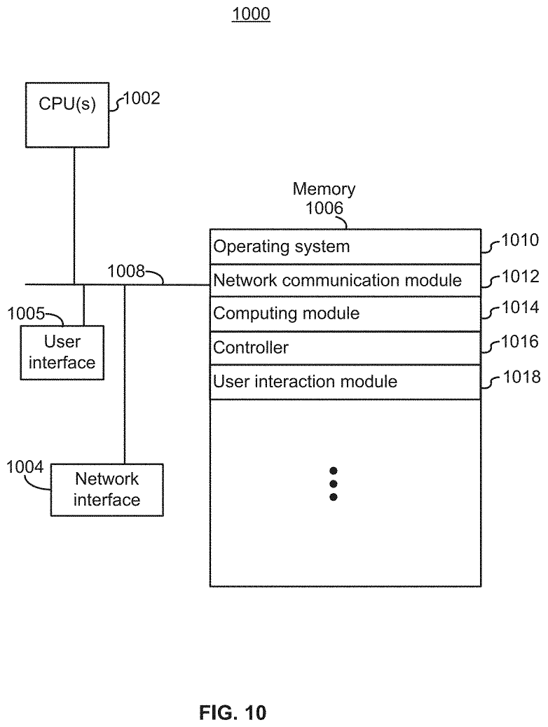

FIG. 10 is a block diagram illustrating an example computing system 1000 for implementing a neural network using one or more crossbar arrays in accordance with some implementations.

The computer system 1000 may be used to implement at least the crossbars or crossbar arrays shown with references to FIGS. 1 to 8. The computer system 1000 in some implementations includes one or more processing units CPU(s) 1002 (also referred to as processors), one or more network interfaces 1004, optionally a user interface 1005, a memory 1006, and one or more communication buses 1008 for interconnecting these components. The communication buses 1008 optionally include circuitry (sometimes called a chipset) that interconnects and controls communications between system components. The memory 1006 optionally includes high-speed random access memory, such as DRAM, SRAM, DDR RAM, and typically includes non-volatile memory, such as memristor arrays. The memory 1006 optionally includes one or more storage devices remotely located from the CPU(s) 1002. The memory 1006, or alternatively the non-volatile memory device(s) within the memory 1006, comprises a non-transitory computer readable storage medium. In some implementations, the memory 1006 or alternatively the non-transitory computer readable storage medium stores the following programs, modules and data structures, or a subset thereof:
an operating system 1010 (e.g., an embedded Linux operating system), which includes procedures for handling various basic system services and for performing hardware dependent tasks;
a network communication module 1012 for connecting the computer system with one or more other computers via one or more network interfaces (wired or wireless);
a computing module 1014 for executing programming instructions;
a controller 1016 for controlling one or more other computers in accordance with the execution of programming instructions; and
a user interaction module 1018 for enabling a user to interact with the computer system 1000.

One or more of the above identified elements may be stored in one or more of the previously mentioned memory devices, and correspond to a set of instructions for performing a function described above. The above identified modules or programs (e.g., sets of instructions) need not be implemented as separate software programs, procedures or modules, and thus various subsets of these modules may be combined or otherwise re-arranged in various implementations. In some implementations, the memory 1006 optionally stores a subset of the modules and data structures identified above. Furthermore, the memory 1006 may store additional modules and data structures not described above.

Plural instances may be provided for components, operations or structures described herein as a single instance. Finally, boundaries between various components, operations, and data stores are somewhat arbitrary, and particular operations are illustrated in the context of specific illustrative configurations. Other allocations of functionality are envisioned and may fall within the scope of the implementation(s). In general, structures and functionality presented as separate components in the example configurations may be implemented as a combined structure or component. Similarly, structures and functionality presented as a single component may be implemented as separate components. These and other variations, modifications, additions, and improvements fall within the scope of the implementation(s).

It will also be understood that, although the terms “first,” “second,” etc. may be used herein to describe various elements, these elements should not be limited by these terms. These terms are only used to distinguish one element from another. For example, a first column could be termed a second column, and, similarly, a second column could be termed the first column, without changing the meaning of the description, so long as all occurrences of the “first column” are renamed consistently and all occurrences of the “second column” are renamed consistently. The first column and the second are columns both column s, but they are not the same column.

The terminology used herein is for the purpose of describing particular implementations only and is not intended to be limiting of the claims. As used in the description of the implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined (that a stated condition precedent is true)” or “if (a stated condition precedent is true)” or “when (a stated condition precedent is true)” may be construed to mean “upon determining” or “in response to determining” or “in accordance with a determination” or “upon detecting” or “in response to detecting” that the stated condition precedent is true, depending on the context.

The foregoing description included example systems, methods, techniques, instruction sequences, and computing machine program products that embody illustrative implementations. For purposes of explanation, numerous specific details were set forth in order to provide an understanding of various implementations of the inventive subject matter. It will be evident, however, to those skilled in the art that implementations of the inventive subject matter may be practiced without these specific details. In general, well-known instruction instances, protocols, structures, and techniques have not been shown in detail.

The foregoing description, for purpose of explanation, has been described with reference to specific implementations. However, the illustrative discussions above are not intended to be exhaustive or to limit the implementations to the precise forms disclosed. Many modifications and variations are possible in view of the above teachings. The implementations were chosen and described in order to best explain the principles and their practical applications, to thereby enable others skilled in the art to best utilize the implementations and various implementations with various modifications as are suited to the particular use contemplated.

What is claimed is:

1. An apparatus comprising:
a plurality of row wires;
a plurality of column wires; and
a plurality of cross-point devices connecting the plurality of row wires and the plurality of column wires, wherein each cross-point devices comprises
a memristor device, and
a selector device formed on the memristor device, wherein the selector device is configured to:
when in an OFF state, selectively transmit a programming signal to the memristor device; and
switch the memristor device to a predefined resistance state when the programming signal includes a voltage pulse higher than a predefined threshold voltage of the selector device and shorter than a crystallization time of the selector device.

2. The apparatus as claimed in claim 1, wherein the selector device is further configured to, when selectively transmitting the programming signal to the memristor device, temporarily switch itself from the OFF state into an ON state.

3. The apparatus as claimed in claim 1, wherein the selector device is further configured to, when in the OFF state, block a voltage pulse that is lower than the predefined threshold voltage of the selector device.

4. The apparatus as claimed in claim 1, wherein the selector device is further configured to switch from the OFF state to the ON state permanently when a high temperature treatment followed by a slow cooling down process is applied to the selector device.

5. The apparatus as claim in claim 4, wherein the selector device is further configured to, switch from the ON state to the OFF state when the high temperature treatment followed by a fast cooling down process is applied to the selector device.

6. The apparatus as claimed in claim 4, wherein a temperature of the high temperature treatment is higher than 150 degree Fahrenheit.

7. The apparatus as claimed in claim 1, wherein the predefined resistance state is an ON state of the memristor device and the crystallization time is within 100 nanoseconds.

8. The apparatus as claimed in claim 1, wherein the memristor device comprises one of: a memristor, a Ferroelectric Resistance Switching Memory, Phase Change Memory, a Resistive Random-Access Memory (RRAM or ReRAM), a Magnetoresistive Random-Access Memory (MRAM), a Dynamic random-access memory (DRAM), or other devices with tunable resistance.

9. The apparatus as claimed in claim 1, wherein a material from which the selector device is made comprises Ge2SbTe5, chalcogenide materials, or other phase change materials.

10. The apparatus as claimed in claim 1, wherein the memristor device comprises an outer bottom electrode and a first functional layer formed on the outer bottom electrode, and the selector device comprises a second functional layer and an outer top electrode formed on the second functional layer.

11. The apparatus as claim in claim 10, wherein the memristor device further comprises an inner bottom electrode formed between the first functional layer and the second functional layer.

12. The apparatus as claim in claim 11, wherein the selector device further comprises an inner top electrode formed between the second functional layer and the inner bottom electrode.

13. The apparatus as claim in claim 12, wherein the cross-point device further comprises an intermediate layer formed between the memristor device and the selector device.

14. A method of operating a crossbar array comprising:
programming a plurality of memristor devices with a programming signal via a plurality of selector devices that are in an OFF state, wherein each of the selector devices is switched to an ON state temporarily when the programming signal includes a voltage that is higher than a predefined threshold voltage of each of the selector devices;
switching the plurality of selector devices from the OFF state to an ON state by applying a high temperature treatment followed by a slow cooling process; and
accessing the plurality of memristors during one or more inferencing operations.

15. The method as claimed in claim 14, further comprising:
switching the plurality of selector devices from the ON state to the OFF state by applying a high temperature treatment followed by a fast cooling process, after accessing the plurality of memristors and before programing the plurality of memristor devices with a next programming signal.

16. The method as claimed in claim 14, wherein accessing the plurality of memristors includes reading from or writing to the plurality of memristors.

17. A non-transitory computer readable storage medium storing one or more programs, the one or more programs comprising instructions, which when executed by a computing system with one or more processors, cause the computing system to execute a method of:
programming a plurality of memristor devices with a programming signal via a plurality of selector devices in OFF state, wherein each of the selector devices is switched to ON state temporarily when a programming signal is higher than a threshold voltage of the selector device;
switching the plurality of selector devices to ON state by applying a high temperature treatment followed by a slow cooling process; and
accessing the plurality of memristors during one or more inferencing operations.

18. The non-transitory computer readable storage medium as claimed in claim 17, the method further comprising:
switching the plurality of selector devices from the ON state to the OFF state by applying a high temperature treatment followed by a fast cooling process, after accessing the plurality of memristors and before programing the plurality of memristor devices with a next programming signal.

19. The non-transitory computer readable storage medium as claimed in claim 17, wherein accessing the plurality of memristors includes reading from or writing to the plurality of memristors.
